(19) United States
(12) Patent Application Publication
(10) Pub. No.: US 2008/0067330 A1
(43) Pub. Date: Mar. 20, 2008

(54) Color sensor for vehicle and method for manufacturing the same

(75) Inventor: Atsushi Yamamoto, Nagoya-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/889,534

(22) Filed: Aug. 14, 2007

(30) Foreign Application Priority Data
Sep. 19, 2006 (JP) 2006-252643
Sep. 22, 2006 (JP) 2006-257159

(51) Int. Cl. G01J 3/51; B05D 5/12; H01L 31/0352; B29D 11/00

(52) U.S. Cl. 250/226; 257/440; 264/1.36; 427/74; 257/E31.032

(57) ABSTRACT

A color sensor includes: a substrate; first to third light receiving elements on the substrate; a red light filter for passing a red light and a first near infrared light block filter for blocking a near infrared light on the first light receiving element; a green light filter for passing a green light and a second near infrared light block filter on the second light receiving element; a visible light block filter for blocking a visible light on the third receiving element; and an ultraviolet light block plate disposed over the first and second near infrared light block filters and the visible light block filter.

### CROSS REFERENCE TO RELATED APPLICATIONS

This application is based on Japanese Patent Applications No. 2006-252643 filed on Sep. 19, 2006, and No. 2006-257159 filed on Sep. 22, 2006, the disclosures of which are incorporated herein by reference.

### FIELD OF THE INVENTION

The present invention relates to a color sensor for a vehicle and a method for manufacturing a color sensor.

### BACKGROUND OF THE INVENTION

There is a light distributing control technique in which an image in a vehicle forward direction is picked up by using a vehicle mounting image pickup device at a nighttime running time, and a tail lamp of a preceding vehicle and a head lamp of an opposite vehicle are detected and a high beam/low beam state of a head lamp of a self vehicle is switched, etc. It is necessary to sensitively distinguish disturbance light of the vehicle light (the tail lamp and the head lamp) and an orange-colored reflecting plate, etc. to perform such control.

There is a technique for detecting a color distributing ratio of two colors or three colors as a former example of a distinguishing method for noticing a color of a light source, disclosed in, for example, U.S. Pat. No. 6,774,988.

However, a near infrared spectroscopic sensitivity area of a color image pickup element is cut to improve distinguishing sensitivity. Therefore, it cannot be applied to application requiring spectroscopic sensitivity of the near infrared area such as a rain droplet sensor (rain sensor), a camera for nighttime monitoring, etc. This becomes an evil when the functions of a sensor group mounted to the vicinity of an inside rear view mirror are intensively collected and a mounting space is saved.

Further, there is a subject when a visible area of two colors or more and the spectroscopic sensitivity of the near infrared area are obtained by the same image pickup element. A general purpose color filter has the spectroscopic sensitivity of the near infrared area. Therefore, it is general that a near infrared light cut glass is separately overlapped, or a spectroscopic sensitivity characteristic of the image pickup element itself is designed so as to be limited to a visible area. In each case, there is a room of a device when existence/nonexistence of the near infrared sensitivity is given in a pixel unit of the color image pickup element.

Thus, it is required for a color sensor for vehicle to easily cope with sensing of light of the near infrared area as well as sensing of light of the visible area.

Further, it is considered that vehicle control is performed by judging a circumferential situation of a self vehicle by using a color sensor for vehicle mounting. In this color sensor for vehicle mounting, a humidity resisting property and a light resisting property are particularly required in comparison with a public welfare use in mounting of a color image pickup element. Concretely, an area except for a light receiving portion including a bonding wire for electrically connecting the image pickup element and a lead frame is covered with mold resin from a view point of the humidity resisting property (disclosed in, e.g., JP-A-20001-77248). However, no consideration with respect to the light resisting property is performed.

Thus, it is required to provide a color sensor for vehicle mounting excellent in the humidity resisting property and the light resisting property.

### SUMMARY OF THE INVENTION

In view of the above-described problem, it is an object of the present disclosure to provide a color sensor for a vehicle. It is another object of the present disclosure to provide a method for manufacturing a color sensor.

According to a first aspect of the present disclosure, a color sensor includes: a substrate; first to third light receiving elements disposed on a surface of the substrate, wherein each of the first to third light receiving elements outputs an electric signal corresponding to an amount of light in an ultraviolet light range, a visible light range and a near infrared light range; a red light filter for selectively passing a red light; a first near infrared light block filter for blocking a near infrared light, wherein the first near infrared light block filter and the red light filter are disposed on the first light receiving element in this order; a green light filter for selectively passing a green light; a second near infrared light block filter for blocking the near infrared light, wherein the second near infrared light block filter and the green light filter are disposed on the second light receiving element in this order; a visible light block filter for blocking a visible light, wherein the visible light block filter is disposed on the third receiving element; and an ultraviolet light block plate disposed over the first and second near infrared light block filters and the visible light block filter.

In the above sensor, when a visible light is entered into the sensor, the first light receiving element detects the red light, and the second light receiving element detects the green light. Further, when the near infrared light is entered into the sensor, the third light receiving element detects the near infrared light. Thus, not only the visible light but also the near infrared light can be detected by the sensor.

According to a second aspect of the present disclosure, a method for manufacturing the color sensor is provided. The sensor is defined in the first aspect of the present disclosure, and further defined such that the first near infrared light block filter is made of a thin film, the second near infrared light block filter is made of another thin film, and the visible light block filter is made of further another thin film.

The method includes: arranging the first to third light receiving elements on the substrate; forming the red light filter on the first light receiving element, and forming the green light filter on the second light receiving element; forming a SOG film on a whole surface of the substrate including the red and green light filters; and forming a thin film on the SOG film and patterning the thin film for providing the first and second near infrared light block filters; and forming another thin film on the SOG film and patterning the another thin film for providing the visible light block filter.

The above method provides the color sensor capable of detecting not only the visible light but also the near infrared light. Further, the red light filter and the green light filter are protected from chemicals by using the SOG film in a manufacturing process.

According to a third aspect of the present disclosure, a color sensor includes: a silicon substrate having a first conductive type; a first impurity diffusion region having a second conductive type and disposed on a surface portion of the substrate; a second impurity diffusion region having the first conductive type and disposed on a surface portion of the first impurity diffusion region; and a third impurity diffusion region having the second conductive type and disposed on a surface portion of the second impurity diffusion region. A boundary between the first impurity diffusion region and the substrate provides a first PN junction for photoelectric converting a near infrared light at the first PN junction. A boundary between the second impurity diffusion region and the first impurity diffusion region provides a second PN junction for photoelectric converting a red light at the second PN junction. A boundary between the third impurity diffusion region and the second impurity diffusion region provides a third PN junction for photoelectric converting a green light at the second PN junction.

In the above sensor, when a visible light is entered into the sensor, the second PN junction detects the red light, and the third PN junction detects the green light. Further, when the near infrared light is entered into the sensor, the first PN junction detects the near infrared light. Thus, not only the visible light but also the near infrared light can be detected by the sensor.

According to a fourth aspect of the present disclosure, a color sensor includes: a color image element including a substrate, a plurality of light receiving elements and a color filter, wherein each light receiving element is disposed on a surface of the substrate, and the color filter is disposed over the plurality of light receiving elements, and wherein each light receiving element outputs an electric signal corresponding to amount of light; a lead frame, on which the color image element is disposed; a bonding wire for electrically bonding the color image element and the lead frame; a ultraviolet light block plate for blocking an ultraviolet light and made of glass, wherein the ultraviolet light block plate is bonded to a light receiving surface of the color image element with a visible light curing adhesion member; and a resin mold for molding the bonding wire and the color image element other than the light receiving surface of the color image element.

In the above sensor, since the resin mold covers the bonding wire and the color image element other than the light receiving surface, the sensor has high humidity resistance. Further, the ultraviolet light blocking plate compensates light resistance of the color filter. Furthermore, the visible light curing adhesion member bonds the color image element and the ultraviolet light plate without using a ultraviolet light curing adhesion member. Thus, the sensor has high humidity resistance and high light resistance.

According to a fifth aspect of the present disclosure, a method for manufacturing the color sensor according to the fourth aspect of the present disclosure is provided. The method includes: mounting the color image element on the lead frame; electrically coupling the color image element and the lead frame with the bonding wire; bonding the ultraviolet light block plate to the light receiving surface of the color image element with the visible light curing adhesion member; and sealing the bonding wire and the color image element other than the light receiving surface of the color image element with the resin mold by using a metal die. The visible light curing adhesion member has a thickness, which is larger than a diameter of a particle in atmosphere in the bonding the ultraviolet light block plate.

The above method provides the sensor having has high humidity resistance and high light resistance. Further, in the step of sealing the bonding wire and the color image element with the resin mold, mechanical damage to the sensor caused by the particle is reduced.

According to a sixth aspect of the present disclosure, a color sensor includes: a color image element including a substrate, a plurality of light receiving elements and a color filter, wherein each light receiving element is disposed on a surface of the substrate, and the color filter is disposed over the plurality of light receiving elements, and wherein each light receiving element outputs an electric signal corresponding to amount of light; a lead frame, on which the color image element is disposed; a bonding wire for electrically bonding the color image element and the lead frame; a transparent resin mold for molding the bonding wire and the color image element; and a ultraviolet light block filter for blocking an ultraviolet light, wherein the ultraviolet light block filter is disposed on the transparent resin mold over a light receiving surface of the color image element. The above sensor has high humidity resistance and high light resistance.

According to a seventh aspect of the present disclosure, a color sensor includes: a color image element including a substrate, a plurality of light receiving elements and a color filter, wherein each light receiving element is disposed on a surface of the substrate, and the color filter is disposed over the plurality of light receiving elements, and wherein each light receiving element outputs an electric signal corresponding to amount of light; a lead frame, on which the color image element is disposed; a bonding wire for electrically bonding the color image element and the lead frame; a ultraviolet light block filter for blocking an ultraviolet light, wherein the ultraviolet light block filter is disposed on a light receiving surface of the color image element through a SOG film; and a resin mold for molding the bonding wire and the color image element other than the light receiving surface of the color image element. The above sensor has high humidity resistance and high light resistance.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic constructional view of a light controller for a vehicle in a first embodiment mode;

FIG. 2 is a constructional view of an optical system of a color sensor for vehicle mounting in this embodiment mode;

FIG. 3 is a perspective view of an image pickup element with a cover glass of the color sensor for vehicle mounting;

FIG. 4A is a plan view of the image pickup element with the cover glass of the color sensor for vehicle mounting in the first embodiment mode, and FIG. 4B is a longitudinal sectional view on line IVB-IVB of FIG. 4A, and FIG. 4C is a longitudinal sectional view on line IVC-IVC of FIG. 4A;

FIG. 5A is a plan view of the image pickup element of the color sensor for vehicle mounting, and FIG. 5B is a longitudinal sectional view on line VB-VB of FIG. 5A, and FIG. 5C is a longitudinal sectional view on line VC-VC of FIG. 5A;

FIG. 6A is a plan view of the image pickup element of the color sensor for vehicle mounting in a removing state of a filter from FIGS. 5A to 5C, and FIG. 6B is a longitudinal sectional view on line VIB-VIB of FIG. 6A, and FIG. 6C is a longitudinal sectional view on line VIC-VIC of FIG. 6A;

FIG. 7 is a view showing an advancing direction of the vehicle front;

FIG. 8 is a view showing an image after processing;

FIG. 9A is a plan view of an image pickup element with a cover glass of a color sensor for vehicle mounting in a second embodiment mode, and FIG. 9B is a longitudinal sectional view on line IXB-IXB of FIG. 9A and FIG. 9C is a longitudinal sectional view on line IXC-IXC of FIG. 9A;

FIG. 10A is a plan view of an image pickup element with a cover glass of a color sensor for vehicle mounting in a third embodiment mode, and FIG. 10B is a longitudinal sectional view on line XB-XB of FIG. 10A and FIG. 10C is a longitudinal sectional view on line XC-XC of FIG. 10A;

FIG. 11A is a plan view of an image pickup element with a cover glass of a color sensor for vehicle mounting in a fourth embodiment mode, and FIG. 11B is a longitudinal sectional view on line XIB-XIB of FIG. 11A and FIG. 11C is a longitudinal sectional view on line XIC-XIC of FIG. 11A;

FIG. 12 is a cross-sectional view of an image pickup element with a cover glass of a color sensor for vehicle mounting in a fifth embodiment mode;

FIGS. 13A to 13E are cross-sectional views showing a manufacturing process of the color sensor for vehicle mounting in the fifth embodiment mode;

FIGS. 14A to 14D are cross-sectional views showing the manufacturing process of the color sensor for vehicle mounting in the fifth embodiment mode;

FIGS. 15A and 15B are cross-sectional views showing the manufacturing process of the color sensor for vehicle mounting in the fifth embodiment mode;

FIG. 16 is a cross-sectional view showing the manufacturing process of the color sensor for vehicle mounting in the fifth embodiment mode;

FIG. 17 is a cross-sectional view of an image pickup element of a color sensor for vehicle mounting in a sixth embodiment mode;

FIG. 18 is a cross-sectional view of the image pickup element of the color sensor for vehicle mounting in the sixth embodiment mode;

FIG. 19 is a cross-sectional view of a color image pickup element package of a color sensor for vehicle mounting in a seventh embodiment mode;

FIG. 20A is a plan view of a color image pickup element with a cover glass, and FIG. 20B is a longitudinal sectional view on line XXB-XXB of FIG. 20A, and FIG. 20C is a longitudinal sectional view on line XXC-XXC of FIG. 20A;

FIG. 21A is a plan view of the color image pickup element, and FIG. 21B is a longitudinal sectional view on line XXIB-XXIB of FIG. 21A, and FIG. 21C is a longitudinal sectional view on line XXIC-XXIC of FIG. 21A;

FIG. 22 is a cross-sectional view of a color image pickup element package of a color sensor for vehicle mounting in an eighth embodiment mode;

FIG. 23 is a cross-sectional view of a main portion of the color image pickup element package in the eighth embodiment mode;

FIG. 24A is a cross-sectional view of a color image pickup element package of a color sensor for vehicle mounting in a ninth embodiment mode, and FIG. 24B is a partially enlarged cross-sectional view showing a part XXIVB of the color image pickup element in FIG. 24A;

FIG. 25A is a cross-sectional view for explaining a manufacturing process of the color image pickup element package, and FIG. 25B is a partially enlarged cross-sectional view showing a part XXVB of the color image pickup element in FIG. 25A;

FIG. 26A is a cross-sectional view for explaining the manufacturing process of the color image pickup element package, FIG. 26B is a partially enlarged cross-sectional view showing a part XXVIB of the color image pickup element in FIG. 26A, and FIG. 26C is a partially enlarged cross-sectional view showing a part XXVIC of the color image pickup element in FIG. 26A

FIG. 27A is a cross-sectional view for explaining the manufacturing process of the color image pickup element package, and FIG. 27B is a partially enlarged cross-sectional view showing a part XXVIIB of the color image pickup element in FIG. 27A;

FIG. 28 is a cross-sectional view for explaining the manufacturing process of the color image pickup element package;

FIG. 29 is a cross-sectional view of a color image pickup element package of a color sensor for vehicle mounting in a tenth embodiment mode;

FIG. 30 is a cross-sectional view of a color image pickup element package of a color sensor for vehicle mounting in an eleventh embodiment mode; and

FIG. 31 is a cross-sectional view of a main portion of the color image pickup element package in the eleventh embodiment mode.

### DETAILED DESCRIPTION OF THE PREFERRED EMBODIMENTS

### First Embodiment Mode

A first embodiment mode will next be explained in accordance with the drawings.

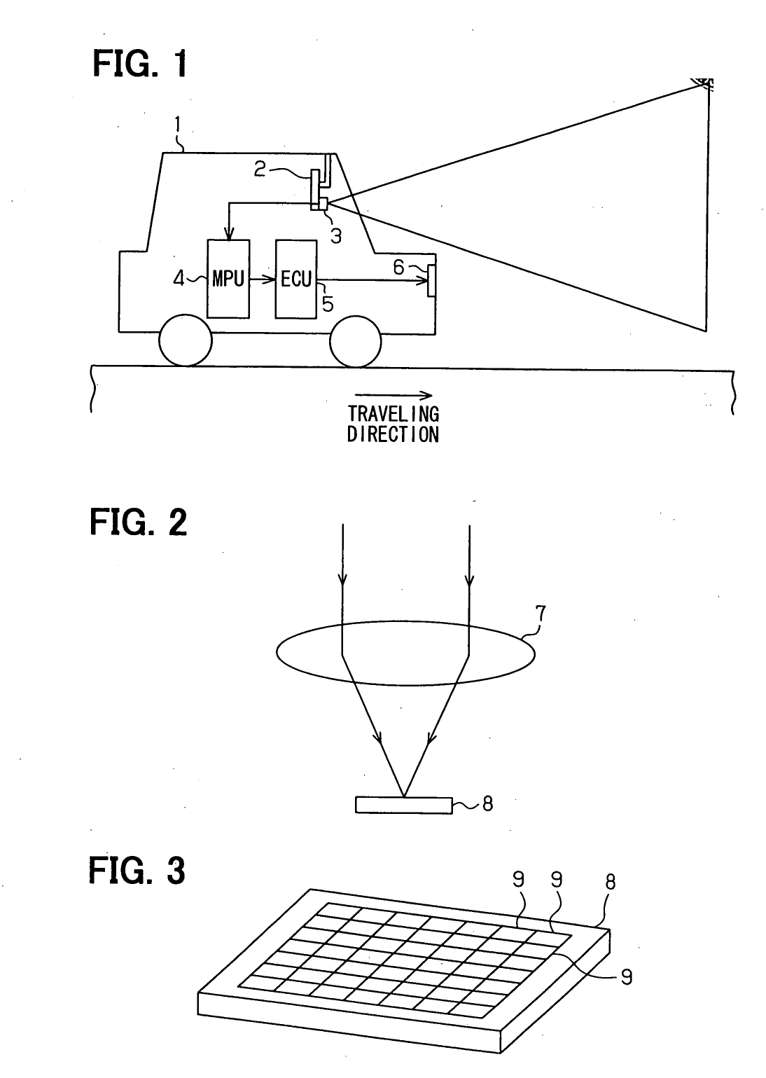

In this embodiment mode, a light controller for a vehicle is provided, and FIG. 1 shows its entire schematic construction.

In FIG. 1, a color sensor for vehicle mounting (image pickup device) 3 is arranged on the rear face of an inside rear view mirror 2 of a vehicle 1. A forward image in an advancing direction of the vehicle 1 can be picked up by this color sensor 3 for vehicle mounting. The color sensor 3 for vehicle mounting is connected to a microprocessor 4, and picked-up image data picked up by the color sensor 3 for vehicle mounting are sent to the microprocessor 4. The microprocessor 4 executes various kinds of processing from the picked-up image data and can detect a tail lamp of a preceding vehicle and a head lamp of an opposite vehicle from the picked-up image data.

An electronic control unit (ECU) 5 for light control is connected to the microprocessor 4, and the operation of the head lamp 6 can be controlled by the electronic control unit 5. Namely, the electronic control unit 5 controls the head lamp 6 to high beam/low beam on the basis of the existence and nonexistence of the forward vehicle (the tail lamp of the preceding vehicle and the head lamp of the opposite vehicle) using the microprocessor 4.

FIG. 2 is a constructional view of an optical system of the color sensor 3 for vehicle mounting. In FIG. 2, an image pickup element 8 with a cover glass is arranged in a focal position of a lens 7. Light from a vehicle forward direction is converged to the image pickup element 8 with the cover glass through the lens 7.

FIG. 3 is a perspective view of the image pickup element 8 with the cover glass of the color sensor 3 for vehicle mounting. In FIG. 3, the image pickup element 8 with the cover glass of the color sensor 3 for vehicle mounting has many pixels 9.

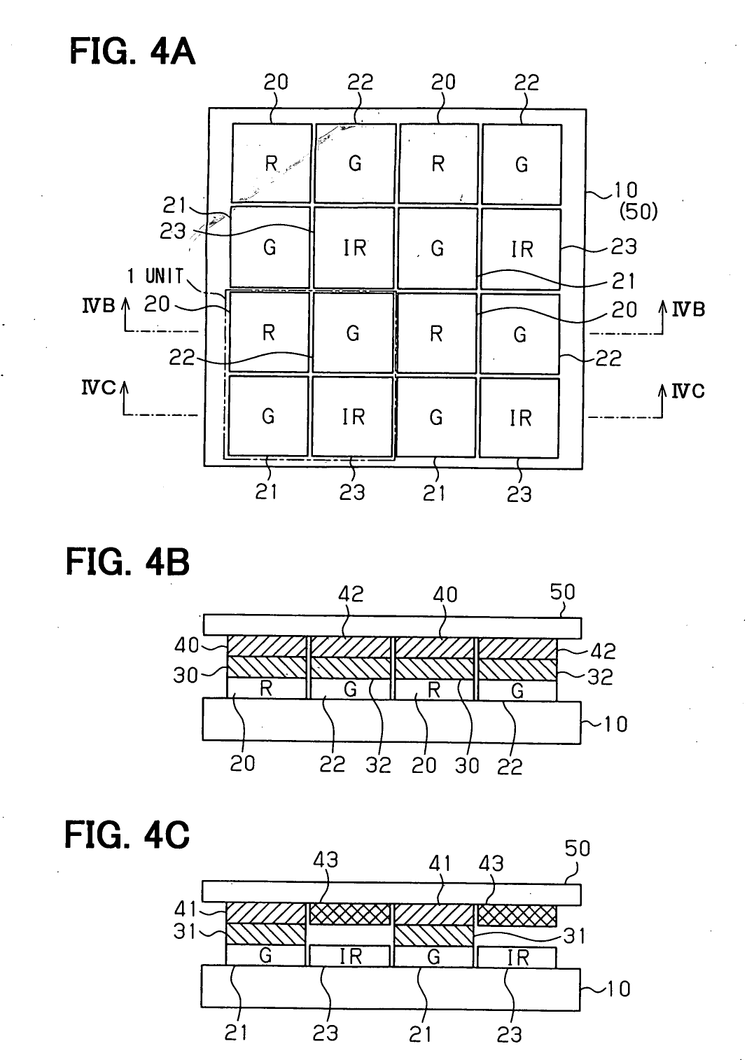

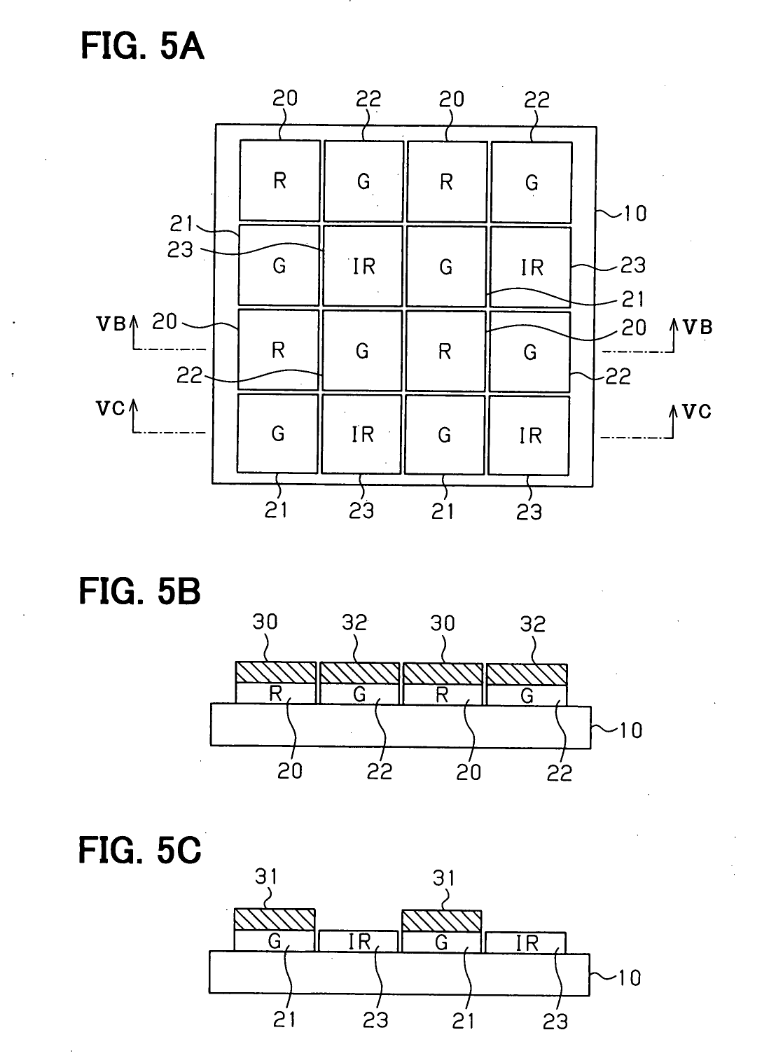

FIG. 4A is a plan view of the image pickup element with the cover glass of the color sensor for vehicle mounting, and FIG. 4B is a longitudinal sectional view on line IVB-IVB of FIG. 4A, and FIG. 4C is a longitudinal sectional view on line IVC-IVC of FIG. 4A. FIGS. 5A to 5C show a state of only the image pickup element by detaching an ultraviolet ray cut glass plate 50 as the cover glass and cut filters 40, 41, 42, 43 in FIGS. 4A to 4C. FIG. 5A is a plan view of the image pickup element of the color sensor for vehicle mounting. FIG. 5B is a longitudinal sectional view on line VB-VB of FIG. 5A. FIG. 5C is a longitudinal sectional view on line VC-VC of FIG. 5A.

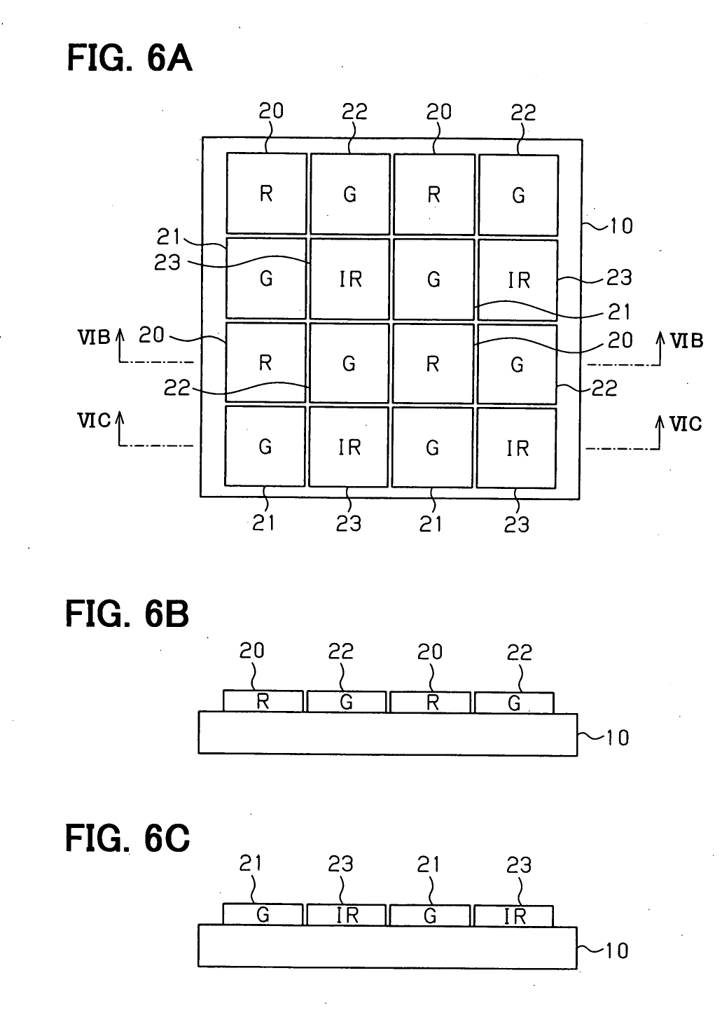

FIGS. 6A to 6C show a removing state of filters 30, 31, 32 in FIGS. 5A to 5C. FIG. 6A is a plan view of the image pickup element of the color sensor for vehicle mounting. FIG. 6B is a longitudinal sectional view on line VIB-VIB of FIG. 6A. FIG. 6C is a longitudinal sectional view on line VIC-VIC of FIG. 6A.

In FIGS. 6A to 6C, as shown by reference numerals 20, 21, 22, 24, many light receiving elements for outputting an electric signal according to the quantity of light of an ultraviolet area, a visible area and a near infrared area are arrayed longitudinally and transversally on the upper face of a substrate 10. A pixel is constructed by the light receiving elements (20 to 23), and a silicon photo diode is used as each light receiving element (20 to 23).

Here, an adjacent light receiving element will be explained with four light receiving elements in total of two adjacent longitudinal light receiving elements and two adjacent transversal light receiving elements as one unit (see FIGS. 4A to 4C). Namely, all the four adjacent light receiving elements have the same construction in each unit with the four light receiving elements as one unit.

In FIGS. 5A to 5C, a red filter 30 for selectively passing red light is arranged on the light receiving element 20. A green filter 31 for selectively passing green light is formed on the light receiving element 21. A green filter 32 for selectively passing green light is formed on the light receiving element 22.

In FIGS. 4A to 4C, the ultraviolet ray cut glass plate 50 is arranged above the substrate 10 so as to be opposed to the substrate 10. Near infrared light cut filters 40, 41, 42 and a visible light cut filter 43 are formed on a lower face of the ultraviolet ray cut glass plate 50. The near infrared light cut filter 40 is arranged on the red filter 30. The near infrared light cut filter 41 is arranged on the green filter 31. The near infrared light cut filter 42 is arranged on the green filter 32. The visible light cut filter 43 is arranged on the light receiving element 23.

Thus, the near infrared light cut filter 40 is arranged on the light receiving element 20 through the red filter 30 for selectively passing red light. Further, the near infrared light cut filters 41, 42 are arranged on the light receiving elements 21, 22 through the green filters 31, 32 for selectively passing green light. Further, the visible light cut filter 43 is arranged on the light receiving element 23. Further, the ultraviolet ray cut glass plate 50 is arranged on the entire face of the visible light cut filter 43 so as to be opposed to the substrate 10.

Accordingly, with respect to light incident from the exterior of a vehicle, light of the ultraviolet area is cut by the ultraviolet ray cut glass plate 50, and light of the near infrared area is cut by the near infrared light cut filter 40. Further, red light is photoelectrically converted in the light receiving element 20 through the red filter 30. Further, with respect to the light incident from the vehicle exterior, light of the ultraviolet area is cut by the ultraviolet ray cut glass plate 50, and light of the near infrared area is cut by the near infrared light cut filters 41, 42. Green light is photoelectrically converted in the light receiving elements 21, 22 through the green filters 31, 32. Further, with respect to the light incident from the vehicle exterior, light of the ultraviolet area is cut by the ultraviolet ray cut glass plate 50, and visible light is cut by the visible light cut filter 43, and near infrared light is photoelectrically converted in the light receiving element 23.

Thus, a pixel arranging structure of basic four pixels of the color image pickup element with the cover glass becomes red (R), green (G) and green (G) of the visible area, and infrared (IR) of the near infrared area. Further, it is possible to prevent that a color filter material is deteriorated by an ultraviolet ray by using the ultraviolet ray cut glass plate 50 as the cover glass (a UV resisting property can be improved).

Thus, in the image pickup element using a general purpose color filter, it is necessary to cut an accompanying near infrared area in pixels for red (R) and green (G). It is also necessary to cut the visible area in a pixel for near infrared (IR). Therefore, a near infrared light cut filter and a visible light cut filter are formed in the ultraviolet ray cut glass plate 50, and an image pickup element with a cover glass having predetermined desirable color characteristics is realized.

Next, the operation of the light controller for a vehicle will be explained.

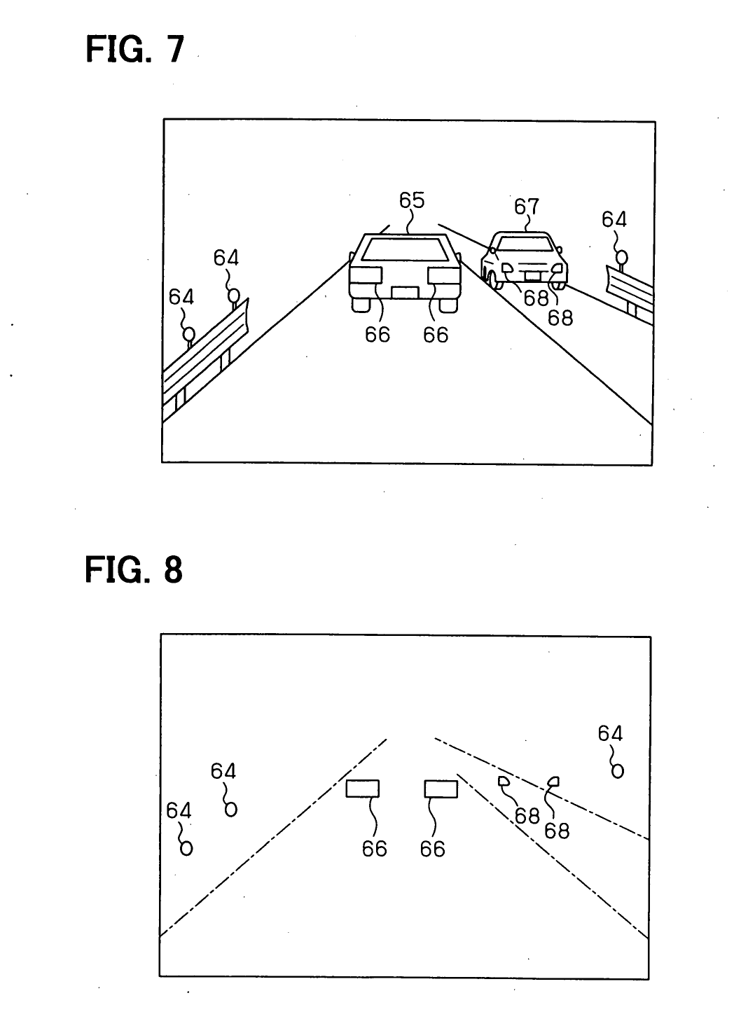

Now, as shown in FIG. 7, the vehicle runs a road arranging an orange-colored reflecting plate 64 therein at night, and there are a preceding vehicle 65 and an opposite vehicle 67, and a tail lamp 66 and a head lamp 68 are turned on. An image is picked up by the color sensor 3 for vehicle mounting and is processed by the microprocessor 4. Thus, as shown in FIG. 8, red light is extracted and the tail lamp 66 of the preceding vehicle can be detected. Thus, it is possible to recognize that there is a preceding vehicle in nighttime running.

Namely, the head lamp 68 of the opposite vehicle is easily recognized since this head lamp 68 is comparatively light. However, the tail lamp 66 of the preceding vehicle is dark. Therefore, the orange-colored reflecting plate 64 and other disturbance light are easily recognized in error as a tail lamp of another vehicle. However, in this embodiment mode, the tail lamp of the preceding vehicle and another light can be discriminated by utilizing that the tail lamp is a red color (the red light of the tail lamp and white color and orange color lights as disturbance light can be distinguished).

In particular, it is possible to more accurately grasp whether it is red light or not by taking a ratio of the green light and the red light. With respect to the red light, an output of the green light is small in comparison with the output of the red light. With respect to light except for the red light, e.g., white color light, a ratio of the output of the green light and the output of the red light is a value close to “1”. Thus, the white color light and the orange-colored light from the reflecting plate, and the red light from the tail lamp of the preceding vehicle can be distinguished.

The operation of the head lamp 6 of the self vehicle is controlled on the basis of this result. For example, when there is a vehicle (a preceding vehicle and an opposite vehicle) in the forward direction of the self vehicle at night, the head lamp of the self vehicle is set to a low beam.

Thus, the tail lamp 66 of the preceding vehicle 65 and the head lamp 68 of the opposite vehicle 67 are detected and light distributing control of the head lamp 6 is performed. In a former example, red (R), green (G) and blue (B) of the visible area are set as a pixel arranging structure of the color image pickup element having its function, and no near infrared area is arranged. However, in this embodiment mode, the arrangement of basic four pixels is set to red (R), green (G), green (G) and the near infrared area (IR) of the visible area. Thus, it can be also applied to an application group requiring spectroscopic sensitivity of the near infrared area of a rain droplet sensor (rain sensor), a camera for nighttime monitoring, etc. by setting the spectroscopic sensitivity of the color sensor to red (R), green (G) and the near infrared area (IR) while detecting performance of the tail lamp and the head lamp of a circumferential vehicle is maintained. When it is used as the camera for nighttime monitoring, light including a near infrared component is emitted from the head lamp of the self vehicle, and its reflected light is received and displayed in a monitor (indicator). Otherwise, near infrared light is emitted in the forward direction of the self vehicle from a projector separated from the head lamp of the self vehicle, and its reflected light is received and displayed in the monitor (indicator). Further, when it is used as the rain droplet sensor (rain sensor), the near infrared light is emitted from the projector within a vehicle room to a front glass and light reflected from a rain droplet attached to the front glass is received and the rain droplet is detected. At this time, the rain droplet can be accurately detected even at night by using the near infrared light.

In accordance with the above embodiment mode, the following effects can be obtained.

(1) As shown in FIGS. 4A to 4C, the substrate 10, many light receiving elements (20, 21, 22, 23), the first near infrared light cut filter 40, the second near infrared light cut filters 41, 42, the visible light cut filter 43 and the ultraviolet ray cut glass plate 50 are arranged. The many light receiving elements (20, 21, 22, 23) are arrayed on the upper face of the substrate 10 and output an electric signal according to the quantity of light of the ultraviolet area, the visible area and the near infrared area. The first near infrared light cut filter 40 is arranged through the red filter 30 for selectively passing red light on the first light receiving element 20 among adjacent light receiving elements. The second near infrared light cut filters 41, 42 are arranged through the green filters 31, 32 for selectively passing green light on the second light receiving elements 21, 22 among the adjacent light receiving elements. The visible light cut filter 43 is arranged on the third light receiving element 23 among the adjacent light receiving elements. The ultraviolet ray cut glass plate 50 is arranged on the first near infrared light cut filter 40, the second near infrared light cut filters 41, 42 and the visible light cut filter 43. Thus, when light of the visible area is incident, the red light is detected in the first light receiving element 20, and the green light is detected in the second light receiving elements 21, 22. Further, when light of the near infrared area is incident, the light of the near infrared area is detected in the third light receiving element 23. Accordingly, it is possible to provide a color sensor for vehicle mounting able to easily cope with sensing of light of the near infrared area as well as sensing of light of the visible area. Further, it can be made compact and the existence/nonexistence of IR sensitivity can be given in a pixel unit of the color image pickup element.

### Second Embodiment Mode

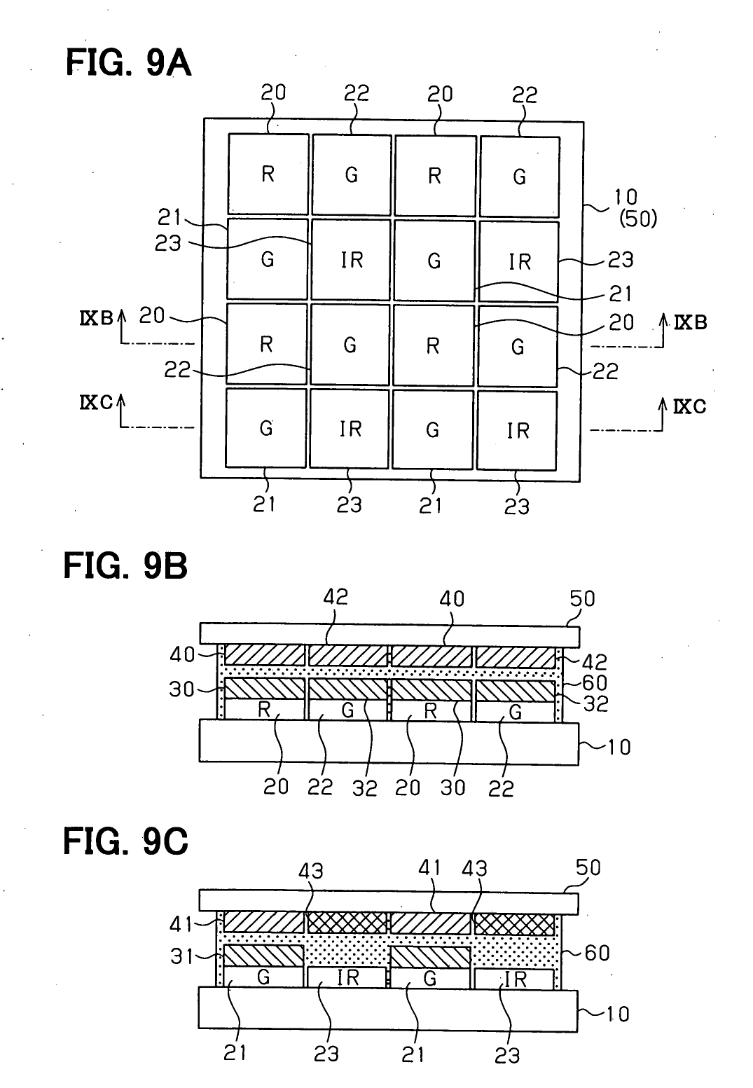

FIGS. 9A to 9C show a color sensor for vehicle mounting in this embodiment mode instead of FIGS. 4A to 4C. FIG. 9A is a plan view of an image pickup element with a cover glass of the color sensor for vehicle mounting. FIG. 9B is a longitudinal sectional view on line IXB-IXB of FIG. 9A. FIG. 9C is a longitudinal sectional view on line IXC-IXC of FIG. 9A.

In FIGS. 9A to 9C, an ultraviolet ray cut glass plate 50 and a substrate 10 (a substrate forming a light receiving element and a color filter) are stuck to each other. A visible light hardening type adhesive 60 is interposed between the substrate 10 and the ultraviolet ray cut glass plate 50. Namely, in a process for sticking the glass plate 50 and the substrate 10, it is necessary to rapidly adhere and harden the glass plate 50 and the substrate 10 after both the glass plate 50 and the substrate 10 are relatively positioned. However, when the ultraviolet ray cut glass plate is used in the glass plate, no ultraviolet ray hardening type adhesive can be used. Accordingly, the visible light hardening type adhesive 60 is used. Thus, the glass plate 50 and the substrate 10 can be easily stuck to each other.

Concretely, a lax track series (an adhesive of an acryl base material) manufactured by Toa Gosei Co., Ltd. can be enumerated as the visible light hardening type adhesive 60.

### Third Embodiment Mode

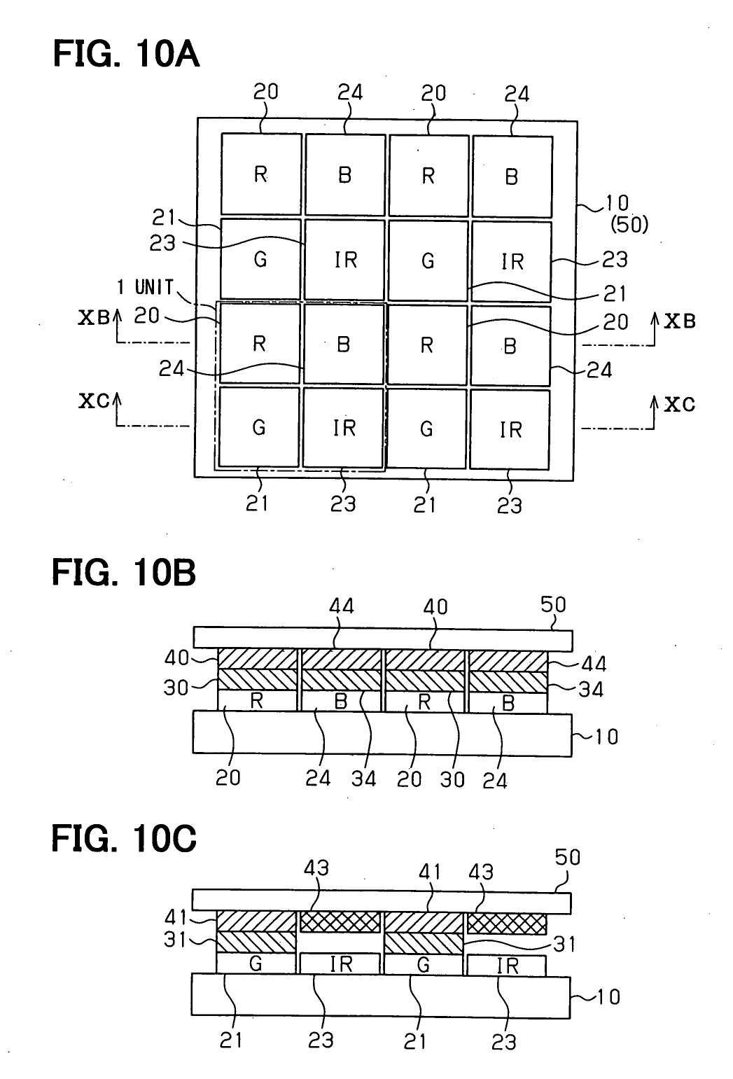

FIGS. 10A to 10C show a color sensor for vehicle mounting in this embodiment mode instead of FIGS. 4A to 4C. FIG. 10A is a plan view of an image pickup element with a cover glass of the color sensor for vehicle mounting. FIG. 10B is a longitudinal sectional view on line XB-XB of FIG. 10A. FIG. 10C is a longitudinal sectional view on line XC-XC of FIG. 10A.

In the first embodiment mode shown in FIGS. 4A to 4C, the arrangement of the basic four pixels is set to red (R), green (G), green (G) and the near infrared area (IR) of the visible area. However, in this embodiment mode shown in FIGS. 10A to 10C, the arrangement of the basic four pixels is set to red (R), green (G), blue (B) and the near infrared area (IR) of the visible area.

Namely, a blue filter 34 for selectively passing blue light is formed on a light receiving element 24 among adjacent light receiving elements on the upper face of the substrate 10. A near infrared light cut filter 44 is arranged on this blue filter 34.

Thus, it may be also set to a construction in which the third near infrared light cut filter 44 arranged through the blue filter 34 for selectively passing blue light is further arranged on the fourth light receiving element 24 among the adjacent light receiving elements. Thus, the blue light can be detected.

### Fourth Embodiment Mode

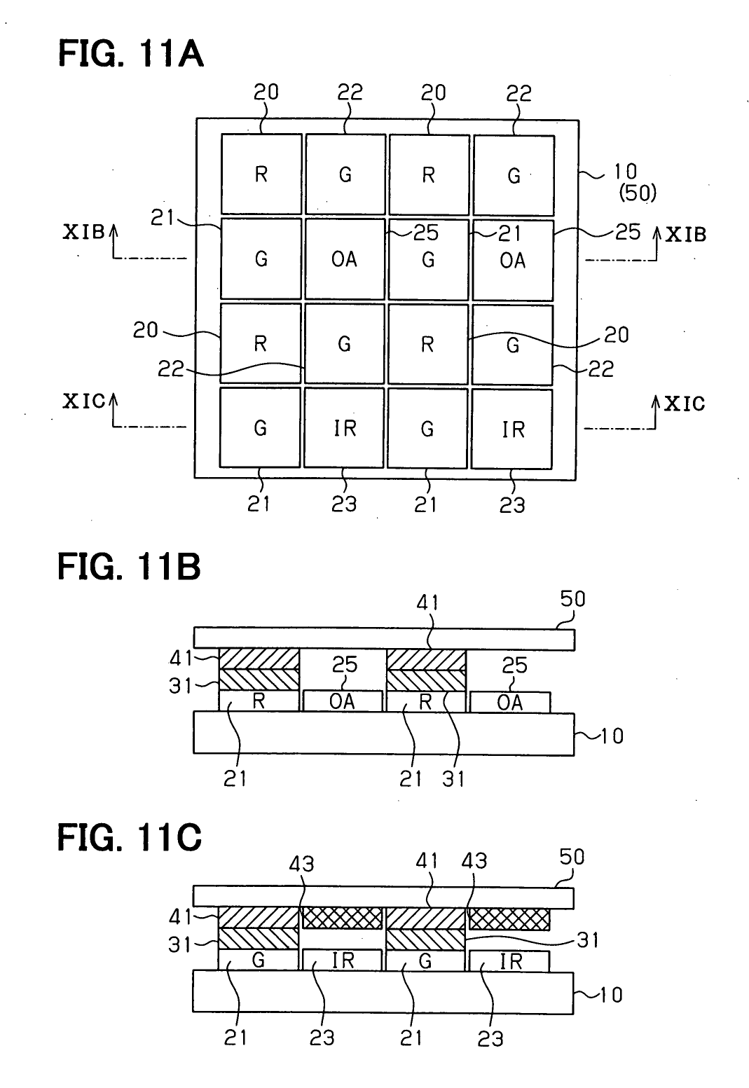

FIGS. 11A to 11C show a color sensor for vehicle mounting in this embodiment mode instead of FIGS. 4A to 4C. FIG. 11A is a plan view of an image pickup element with a cover glass of the color sensor for vehicle mounting. FIG. 11B is a longitudinal sectional view on line XIB-XIB of FIG. 11A. FIG. 11C is a longitudinal sectional view on line XIC-XIC of FIG. 11A.

In FIGS. 11A to 11C, no visible light cut filter is arranged on a light receiving element 25 by changing an arranging pattern of the visible light cut filter 43 in FIGS. 4A to 4C. Namely, light is constructed so as to be received through the ultraviolet ray cut glass plate 50 without interposing a color filter and a cut filter in the light receiving element 25 arrayed on the substrate 10 except for the first to third light receiving elements.

Thus, the light receiving element 25 receives light through the ultraviolet ray cut glass plate 50, and outputs a signal according to the quantity of light of the visible area and the near infrared area except for the ultraviolet area. Namely, light of the visible area and the near infrared area can be detected. An output of this light receiving element 25 can be used as a solar radiation sensor. Namely, this output is utilized as an optical sensor having spectroscopic sensitivity of an entire wavelength area with respect to the near infrared area and the visible area, and can be applied to an auto air-conditioner system.

### Fifth Embodiment Mode

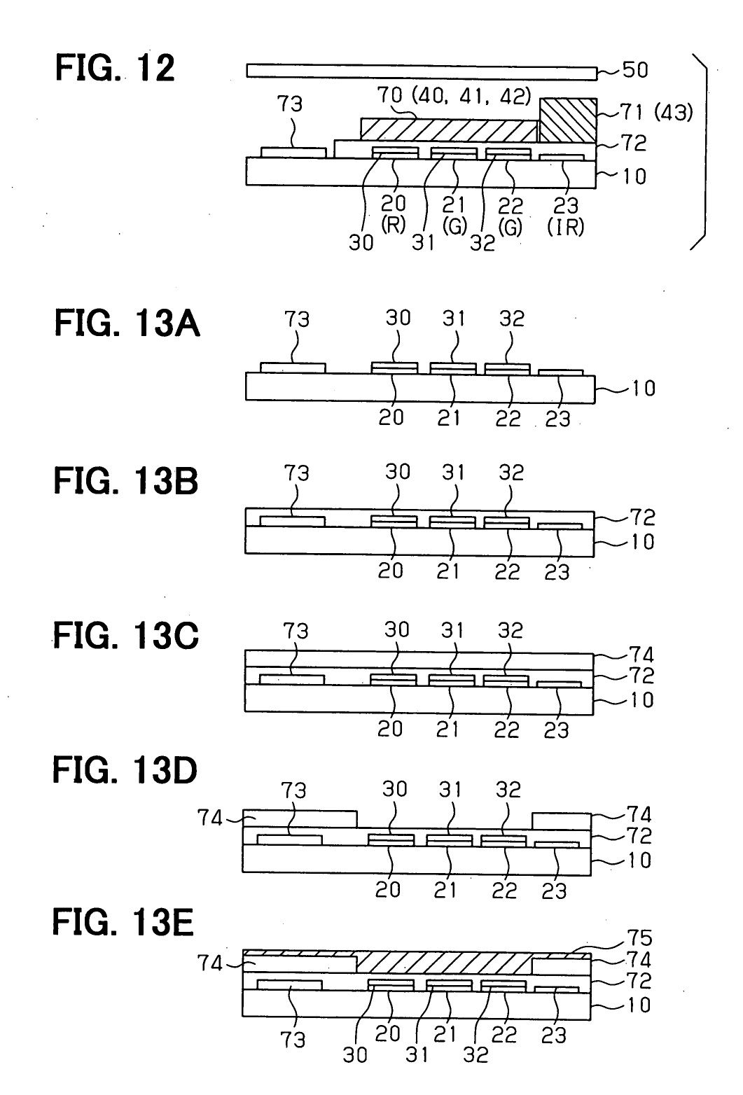

FIG. 12 is a longitudinal sectional view of an image pickup element with a cover glass of a color sensor for vehicle mounting in this embodiment mode.

In FIG. 12, a near infrared light cut filter 40 is arranged through the red filter 30 on the light receiving element 20 on the upper face of the substrate 10. Further, near infrared light cut filters 41, 42 are arranged through the green filters 31, 32 on the light receiving elements 21, 22. A visible light cut filter 43 is arranged on the light receiving element 23. An ultraviolet ray cut glass plate 50 is arranged on the near infrared light cut filters 40, 41, 42 as a thin film 70 and the visible light cut filter 43 as a thin film 71.

Here, an SOG (Spin On Glass) film 72 is formed on the light receiving elements 20, 21, 22, 23 on the substrate 10. The near infrared light cut filters 40, 41, 42 and the visible light cut filter 43 are arranged on this SOG film 72. The near infrared light cut filters 40, 41, 42 and the visible light cut filter 43 are constructed by a thin film. Further, an electrode pad 73 is formed on the upper face of the substrate 10.

In FIG. 12, the light receiving elements 20, 21, 22, 23 are arranged transversally in a line on the substrate 10, but this arrangement is set for an explanation and its arrangement is the same as FIGS. 4A to 4C.

Next, a manufacturing method of the color sensor for vehicle mounting in this embodiment mode will be explained.

As shown in FIG. 13A, the light receiving elements 20, 21, 22, 23 and the electrode pad 73 are formed on the substrate 10, and the red filter 30 is formed on the light receiving element 20 and the green filters 31, 32 are formed on the light receiving elements 21, 22.

Further, as shown in FIG. 13B, the SOG film 72 is formed on the entire face of the substrate 10. Further, as shown in FIG. 13C, a resist 74 is coated on the SOG film 72 on the substrate 10 (is formed on the entire face). Subsequently, as shown in FIG. 13D, the resist 74 is patterned and a near infrared light cut area is removed.

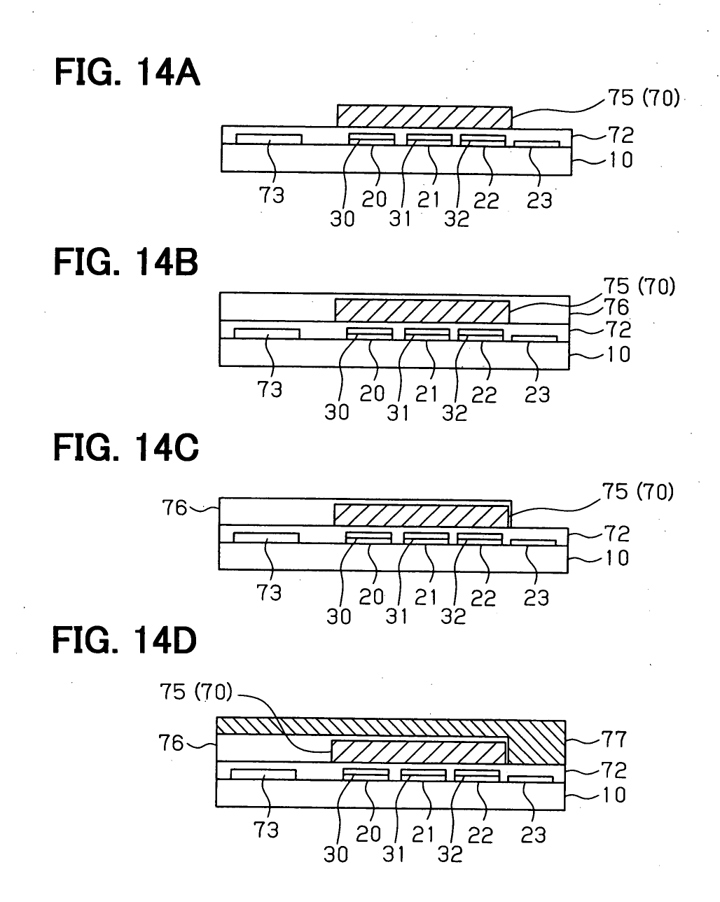

Further, as shown in FIG. 13E, a thin film 75 for a near infrared light cut filter is formed on the entire face of the substrate 10 (on the resist 74) by evaporation. Further, as shown in FIG. 14A, the resist 74 is removed by lift-off and the thin film 75 for a near infrared light cut filter is left in a predetermined area. Namely, the thin film 75 for a near infrared light cut filter is arranged on the light receiving elements 20, 21, 22.

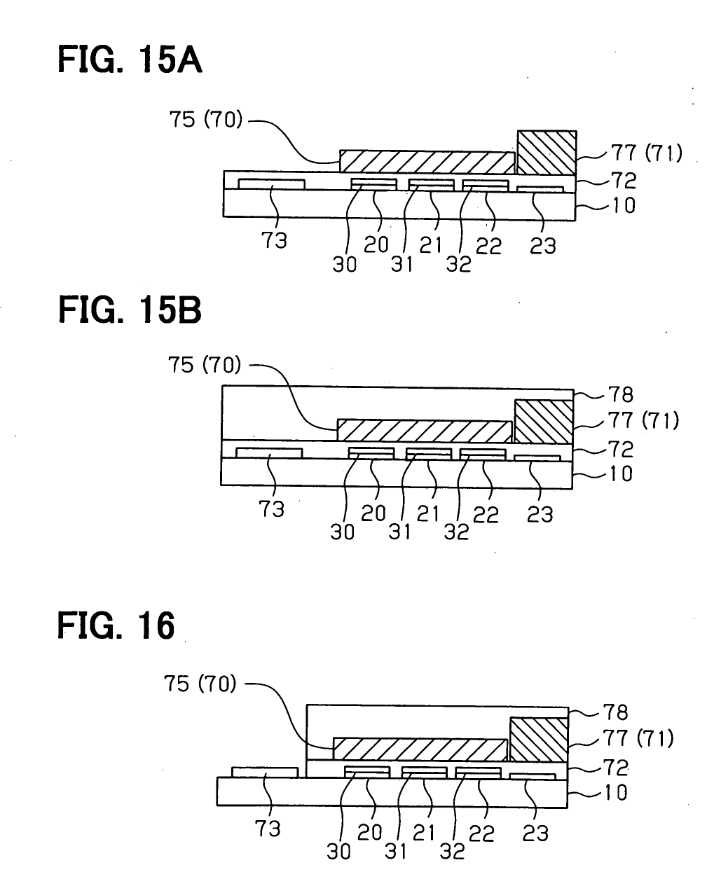

Subsequently, as shown in FIG. 14B, a resist 76 is coated on the substrate 10 (on the thin film 75 for a near infrared light cut filter) (is formed on the entire face). As shown in FIG. 14C, the resist 76 is then patterned and a visible light cut area is removed. Further, as shown in FIG. 14D, a thin film 77 for a visible light cut filter is formed on the entire face of the substrate 10 (on the resist 76) by evaporation. Further, as shown in FIG. 15A, the thin film 77 for a visible light cut filter of an unnecessary area is removed by lift-off and the thin film 77 for a visible light cut filter is left in a predetermined area. Namely, the thin film 77 for a visible light cut filter is arranged on the light receiving element 23.

Subsequently, as shown in FIG. 15B, a resist 78 is coated on the substrate 10 (on the thin film 77 for a visible light cut filter) (is formed on the entire face). As shown in FIG. 16, the resist 78 is then patterned and an electrode pad arranging area is removed. Thereafter, the electrode pad 73 is exposed by performing dry etching with the resist 78 as a mask. When the ultraviolet ray cut glass plate 50 is arranged after the resist 78 is then separated and removed, the color sensor for vehicle mounting shown in FIG. 12 is obtained.

In such a manufacturing process, the SOG film 72 is interposed when the thin film 75 for a near infrared light cut filter and the thin film 77 for a visible light cut filter are formed by a photo process. Accordingly, no color filters 30, 31, 32 are damaged by a medicine liquid.

In the thin film construction of the near infrared light cut filter, an aluminum oxide film (Al₂O₃) may be set to a first layer, and a titanium oxide film (TiO₂) and a silicon oxide film (SiO₂) may be also alternately laminated at a predetermined film thickness. Further, in the thin film construction of the visible light cut filter, a silicon film (Si) and a silicon oxide film (SiO₂) may be also alternately laminated.

In accordance with the above embodiment mode, the following effects can be obtained.

(2) As shown in FIG. 12, since the near infrared light cut filters 40, 41, 42 and the visible light cut filter 43 are constructed by a thin film, the color sensor for vehicle mounting can be easily manufactured by a semiconductor process (can be easily arranged).

(3) In particular, as a manufacturing method of the color sensor for vehicle mounting, as shown in FIG. 13A, many light receiving elements (20, 21, 22, 23) are arrayed on the upper face of the substrate 10. In these light receiving elements, the red filter 30 is formed on the first light receiving element 20, and the green filters 31, 32 are formed on the second light receiving elements 21, 22 (first process). As shown in FIG. 13B, the SOG film 72 is formed on the entire face of the substrate 10 including upper portions of the red filter 30 and the green filters 31, 32 (second process). As shown in FIG. 15A, the thin film 75 for a near infrared light cut filter is patterned on the SOG film 72, and the thin film 77 for a visible light cut filter is patterned on the SOG film 72 (third process). Accordingly, the color sensor for vehicle mounting of the structure of (2) can be manufactured. Further, in a manufacturing process, the red filter 30 and the green filters 31, 32 can be protected from a medicine liquid by the SOG film 72.

(4) Here, as shown in FIG. 13A, the electrode pad 73 is formed on the upper face of the substrate 10 in the first process. As shown in FIG. 16, a fourth process for removing the SOG film 72 on the electrode pad 73 and exposing the electrode pad 73 is included after the third process. Accordingly, the color sensor for vehicle mounting having the electrode pad 73 can be easily manufactured.

### Sixth Embodiment Mode

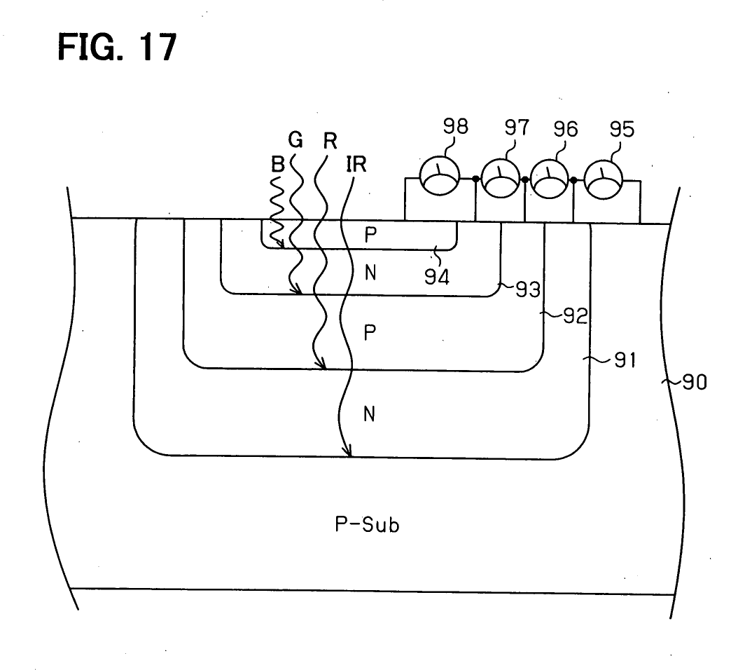

FIG. 17 shows a longitudinal sectional view of an image pickup element of a color sensor for vehicle mounting in this embodiment mode.

In this embodiment mode of FIG. 17, spectroscopic sensitivity is provided by the structure of the color sensor without using a color filter, a cut filter and a cut glass plate.

A deep N-type impurity diffusion area 91 is formed in a surface layer portion of a P-type silicon substrate 90. The P-type silicon substrate 90 is a silicon substrate of a first electric conductivity type as an impurity diffusion area of the first electric conductivity type. In this example, P-type is the first electric conductivity type, and N-type is a second electric conductivity type.

A P-type impurity diffusion area 92 shallower than the N-type impurity diffusion area 91 is formed in a surface layer portion within the N-type impurity diffusion area 91 in the P-type silicon substrate 90. An N-type impurity diffusion area 93 shallower than the P-type impurity diffusion area 92 is formed in a surface layer portion within the P-type impurity diffusion area 92 in the P-type silicon substrate 90. A P-type impurity diffusion area 94 shallower than the N-type impurity diffusion area 93 is formed in a surface layer portion within the N-type impurity diffusion area 93 in the P-type silicon substrate 90.

Accordingly, a PN junction portion of a bottom face of the P-type impurity diffusion area 92 and the N-type impurity diffusion area 91 is located in a position shallower than a PN junction portion of a bottom face of the N-type impurity diffusion area 91 and the P-type silicon substrate 90. In a position shallower than this PN junction portion, a PN junction portion of a bottom face of the N-type impurity diffusion area 93 and the P-type impurity diffusion area 92 is located. In a position shallower than this PN junction portion, a PN junction portion of a bottom face of the P-type impurity diffusion area 94 and the N-type impurity diffusion area 93 is located.

An electric current measuring device 95 is arranged between the P-type silicon substrate 90 and the N-type impurity diffusion area 91. An electric current measuring device 96 is arranged between the N-type impurity diffusion area 91 and the P-type impurity diffusion area 92. An electric current measuring device 97 is arranged between the P-type impurity diffusion area 92 and the N-type impurity diffusion area 93. An electric current measuring device 98 is arranged between the N-type impurity diffusion area 93 and the P-type impurity diffusion area 94.

Light is irradiated to the P-type silicon substrate 90 from an upward direction of the P-type silicon substrate 90 (light is received). Thus, an electric current using an IR photon is flowed in the PN junction portion of the bottom face of the N-type impurity diffusion area 91 and the P-type silicon substrate 90, and is detected in the first electric current measuring device 95. An electric current using a red photon is flowed in the PN junction portion of the bottom face of the P-type impurity diffusion area 92 and the N-type impurity diffusion area 91, and is detected in the second electric current measuring device 96. An electric current using a green photon is flowed in the PN junction portion of the bottom face of the N-type impurity diffusion area 93 and the P-type impurity diffusion area 92, and is detected in the third electric current measuring device 97. An electric current using a blue photon is flowed in the PN junction portion of the bottom face of the P-type impurity diffusion area 94 and the N-type impurity diffusion area 93, and is detected in the fourth electric current measuring device 98. Thus, required spectroscopic sensitivity can be provided.

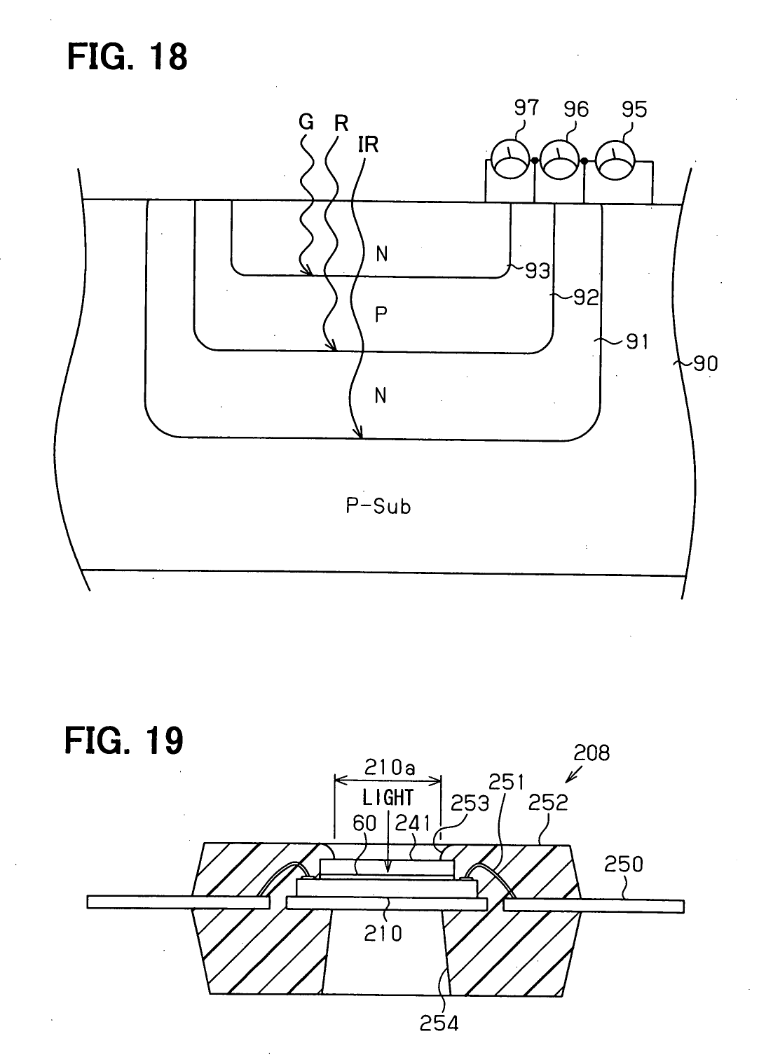

As shown in FIG. 18 instead of FIG. 17, the near infrared light, the red light and the green light may be also detected by removing the P-type impurity diffusion area 94 in FIG. 17.

In accordance with the above embodiment mode, the following effects can be obtained.

(5) The first impurity diffusion area 91 of P-type is formed in a surface layer portion of the P-type silicon substrate 90. The second impurity diffusion area 92 of P-type shallower than the impurity diffusion area 91 is formed in the surface layer portion of the silicon substrate 90 in the impurity diffusion area 91. Further, the third impurity diffusion area 93 of N-type shallower than the impurity diffusion area 92 is formed in the surface layer portion of the silicon substrate 90 in the impurity diffusion area 92. A deepest first PN junction portion for photoelectrically converting the near infrared light is formed at an interface of the bottom face of the impurity diffusion area 91 and the silicon substrate 90. A second deepest second PN junction portion for photoelectrically converting red light is formed at an interface of the bottom face of the impurity diffusion area 92 and the impurity diffusion area 91. A third deepest third PN junction portion for photoelectrically converting green light is formed at an interface of the bottom face of the impurity diffusion area 93 and the impurity diffusion area 92. Thus, when light of the visible area is incident, the red light is detected in the second PN junction portion and the green light is detected in the third PN junction portion. Further, when light of the near infrared area is incident, the light of the near infrared area is detected in the first PN junction portion. Accordingly, it is possible to provide a color sensor for vehicle mounting able to easily cope with sensing of the light of the near infrared area as well as sensing of light of the visible area.

(6) Here, as shown in FIG. 17, the fourth impurity diffusion area 94 of P-type shallower than the impurity diffusion area 93 is further formed in the surface layer portion of the silicon substrate 90 in the third impurity diffusion area 93. A shallowest fourth PN junction portion for photoelectrically converting blue light is formed at an interface of the bottom face of the impurity diffusion area 94 and the impurity diffusion area 93. Accordingly, the blue light can be detected.

The above embodiment mode may be also changed as follows.

In the basic four pixels, red (R), green (G), green (G) and the near infrared area (IR) of the visible area are set. Further, in the basic four pixels, red (R), green (G), blue (B) and the near infrared area (IR) of the visible area are set. Alternatively, red (R), green (G) and the near infrared area (IR) of the visible area may be also set in basic three pixels.

Further, as mentioned above, the light controller, the rain droplet sensor (a camera for nighttime monitoring), etc. have been described in the color sensor for vehicle mounting. Alternatively, another system for sensing light of the visible area and another system for sensing light of the near infrared area may be applied to.

### Seventh Embodiment Mode

In this embodiment mode, a light controller is applied for a vehicle.

FIG. 19 is a cross-sectional view of the color image pickup element package 208. In FIG. 19, a color image pickup element 210 with a cover glass is packaged by resin.

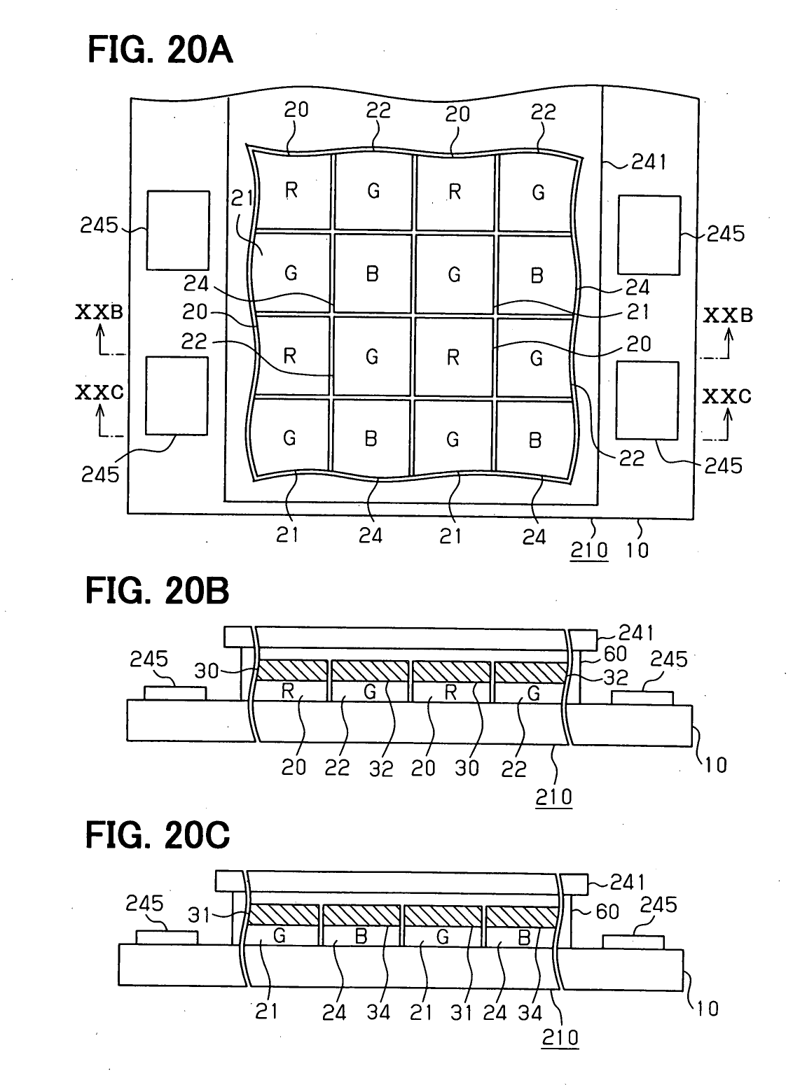

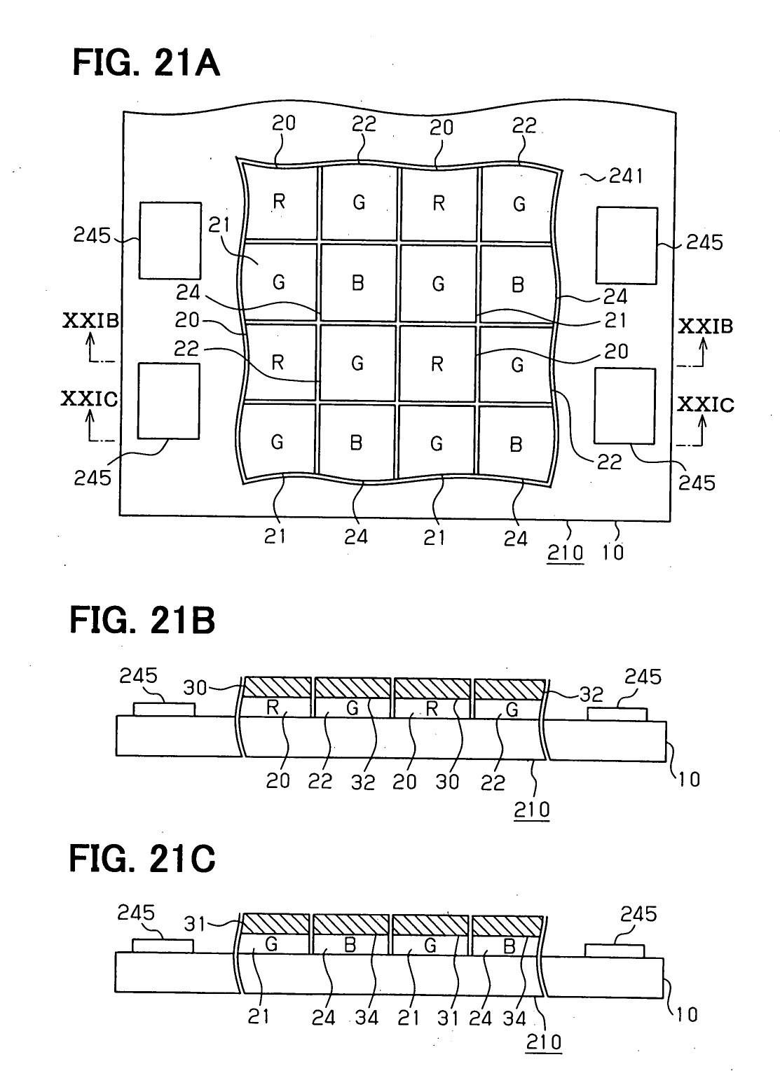

FIG. 20A is a plan view of the color image pickup element with the cover glass, and FIG. 20B is a longitudinal sectional view on line XXB-XXB of FIG. 20A, and FIG. 20C is a longitudinal sectional view on line XXC-XXC of FIG. 20A. FIGS. 21A to 21C show a detaching state of an ultraviolet ray cut glass plate 241 as the cover glass in FIGS. 20A to 20C. FIG. 21A is a plan view of the color image pickup element 210. FIG. 21B is a longitudinal sectional view on line XXIB-XXIB of FIG. 21A. FIG. 21C is a longitudinal sectional view on line XXIC-XXIC of FIG. 21A.

In FIGS. 21A to 21C, many light receiving elements for outputting an electric signal according to the quantity of light as shown by reference numerals 20, 21, 22, 24 are arrayed longitudinally and transversally on the upper face of a substrate 10. A pixel is constructed by the light receiving elements (20 to 22 and 24). A silicon photo diode is used as each light receiving element (20 to 22 and 24). Further, a bonding pad 245 is arranged in an end portion of the upper face of the substrate 10. The image pickup element is constructed in this way.

In FIGS. 21A to 21C, a red filter 30 for selectively passing red light is arranged on the light receiving element 20 of the image pickup element. Further, a green filter 31 for selectively passing green light is formed on the light receiving element 21. Similarly, a green filter 32 for selectively passing green light is formed on the light receiving element 22. Further, a blue filter 34 for selectively passing blue light is formed on the light receiving element 24. Thus, in the color image pickup element 210, many light receiving elements 20, 21, 22, 24 for outputting an electric signal according to the quantity of light are arrayed on the upper face of the substrate 10, and the color filters 30, 31, 32, 34 are formed on the upper faces of the light receiving elements 20, 21, 22, 24.

In FIGS. 20A to 20C, the ultraviolet ray cut glass plate 241 as a cover glass is stuck by a visible light hardening type adhesive 60 on the upper face of a light receiving portion (a part for arraying the light receiving element) as an image pickup area of the color image pickup element 210. The ultraviolet ray cut glass plate 241 is arranged so as to be opposed to the substrate 10. Accordingly, with respect to light incident from the exterior of a vehicle, light of an ultraviolet area is cut by the ultraviolet ray cut glass plate 241. The red light is photoelectrically converted in the light receiving element 20 through the red filter 30. Further, with respect to the light incident from the vehicle exterior, the light of the ultraviolet area is cut by the ultraviolet ray cut glass plate 241. Further, the green light is photoelectrically converted in the light receiving elements 21, 22 through the green filters 31, 32. Further, with respect to the light incident from the vehicle exterior, the light of the ultraviolet area is cut by the ultraviolet ray cut glass plate 241, and the blue light is photoelectrically converted in the light receiving element 24 through the blue filter 34. Thus, a pixel arranging structure of basic four pixels of the color image pickup element 210 becomes red (R), green (G), green (G) and blue (B) of the visible area. Further, it is possible to prevent that a color filter is deteriorated by an ultraviolet ray by using the ultraviolet ray cut glass plate 241 as the cover glass (a UV resisting property can be improved). Further, the surface of the color image pickup element 210 can be mechanically protected by the ultraviolet ray cut glass plate 241 as the cover glass.

In FIG. 19, the color image pickup element 210 is mounted onto a lead frame 250 (more particularly, a die bond portion). The color image pickup element 210 (bonding pad 245) and the lead frame 250 (more particularly, a lead portion) are electrically connected by a bonding wire 251. Further, an area including the bonding wire 251 and removing at least a light receiving portion (image pickup area) 10a of the color image pickup element 210 is sealed by black mold resin 252. More particularly, in the light receiving portion 210a in the color image pickup element 210, there is no mold resin 252 and the light receiving portion 210a is opened. Namely, an opening portion 253 is formed. Further, on a face opposed to an image pickup area in the color image pickup element 210 (substrate 10), there is also no mold resin 252 and this face is opened. Namely, an opening portion 254 is formed.

A lax track series of an acryl base manufactured by Toa Gohsei Co., Ltd. can be enumerated as a concrete example of the visible light hardening type adhesive 60. Further, with respect to characteristics (ultraviolet ray transmittance) of the ultraviolet ray cut glass plate 241, it is set to at least 10% or less with respect to light of a wavelength area of 350 nm or less (transmittance is set to 10% or less). Namely, the ultraviolet ray cut glass plate 241 is preferable when the transmittance of light of the wavelength area of 350 nm or less is 10% or less. Further, it is desirable to set this transmittance to 1% or less (transmittance is set to 1% or less). Namely, the ultraviolet ray cut glass plate 241 is more preferable when the transmittance of light of the wavelength area of 350 nm or less is 1% or less.

The color image pickup element package 208 is assembled as follows.

The color image pickup element 210 is prepared. In the color image pickup element 210, the light receiving elements 20, 21, 22, 24 and the bonding pad 245 are formed on the substrate 10, and the color filters 30, 31, 32, 34 are formed on the light receiving elements 20, 21, 22, 24. The color image pickup element 210 is then arranged and fixed onto the lead frame 250. Further, the lead frame 250 and the color image pickup element 210 are electrically connected by wire bonding. Further, the visible light hardening type adhesive 60 is coated on the upper face of the light receiving portion 210a of the color image pickup element 210. The ultraviolet ray cut glass plate 241 is arranged on this visible light hardening type adhesive 60. Further, visible light is irradiated and the adhesive 60 is hardened and fixed. Thus, after both the color image pickup element 210 and the ultraviolet ray cut glass plate 241 are relatively positioned, the visible light hardening type adhesive 60 is used from necessity for instantaneously fixing the color image pickup element 210 and the ultraviolet ray cut glass plate 241. Finally, sealing is performed by mold resin 252 using a die (molding is performed).

In accordance with the above embodiment mode, the following effects can be obtained.

(7) An area including the bonding wire 251 and removing at least the light receiving portion 210a of the color image pickup element 210 is sealed by mold resin 252 by adopting a mounting structure of the color image pickup element 210 shown in FIG. 19. Thus, it becomes excellent in humidity resisting property. Further, in a manufacturing process, after the color image pickup element and the ultraviolet ray cut glass plate are relatively positioned, it is necessary to instantaneously fix the color image pickup element and the ultraviolet ray cut glass plate. In consideration of this necessity, no hardening process provided by an ultraviolet ray using a normal ultraviolet ray hardening type adhesive can be adopted in characteristics of the ultraviolet ray cut glass plate. Accordingly, the ultraviolet ray cut glass plate 241 is stuck by using a visible light hardening type adhesive. Light resisting property of a color filter can be compensated (UV resisting property compensation) by this ultraviolet ray cut glass plate 241. Thus, a color sensor for vehicle mounting excellent in humidity resisting property and light resisting property can be provided.

### Eighth Embodiment Mode

FIG. 22 is a cross-sectional view of a color sensor for vehicle mounting in this embodiment mode instead of FIG. 19. FIG. 23 is an enlarged view of a wire bonding portion.

In FIGS. 22 and 23, a bonding portion (joining portion) of the bonding wire 251 of the upper face of the substrate 10 is also covered with the visible light hardening type adhesive 60. Thus, the bonding portion of the bonding wire 251 can be protected by the visible light hardening type adhesive 60.

As a mounting process, wire bonding is performed after the color image pickup element 210 is mounted to the lead frame 250 (after die bond). Thereafter, the visible light hardening type adhesive is coated by including a wire bonding portion, and the ultraviolet ray cut glass plate 241 is arranged on this visible light hardening type adhesive. Visible light is then irradiated and the visible light hardening type adhesive is hardened and the ultraviolet ray cut glass plate 241 is stuck. Sealing is then performed by mold resin 252 (molding is performed).

### Ninth Embodiment Mode

FIGS. 24A and 24B are a cross-sectional view of a color sensor for vehicle mounting in this embodiment mode instead of FIG. 19.

As film thickness management of the visible light hardening type adhesive 60, thickness t of the visible light hardening type adhesive 60 is set to be thicker than diameter D of a particle 258 in an atmospheric environment at a sticking time of the ultraviolet ray cut glass plate 241. A detailed explanation will be made by using FIGS. 25A to 28.

As a manufacturing process, the color image pickup element 210 is first prepared. Namely, as shown in FIGS. 21A to 21C, each light receiving element (20, 21, 22, 24) and the bonding pad 245 are formed on the substrate 10, and color filters 30, 31, 32, 34 are formed.

Then, as shown in FIGS. 25A to 25B, in a mounting room R1, the color image pickup element 210 is arranged and fixed onto the lead frame 250. Further, as shown in FIGS. 26A to 26C, the lead frame 250 and the color image pickup element 210 are electrically connected by wire bonding in the mounting room R1. Further, the visible light hardening type adhesive 60 is coated on the upper face of a light receiving portion of the color image pickup element 210. As shown in FIGS. 27A to 27B, the ultraviolet ray cut glass plate 241 is arranged on the upper face of the light receiving portion of the color image pickup element 210 through the visible light hardening type adhesive 60. Further, visible light is irradiated and the adhesive 60 is hardened and fixed.

In the process up to now, thickness t of the visible light hardening type adhesive 60 is set to be greater than particle diameter D of the particle 258 of the mounting room R1.

Then, as shown in FIG. 28, an area including the bonding wire 251 and removing at least a light receiving portion of the color image pickup element 210 is sealed by mold resin 252 as shown in FIGS. 24A to 24B by using a die (a lower die 260 and an upper die 261).

Here, thickness t of the visible light hardening type adhesive 60 is thicker than diameter D of the above particle 258. Accordingly, in the mold resin molding process shown in FIG. 28, the color image pickup element 210 and the ultraviolet ray cut glass plate 241 are pressed between the lower die 260 and the upper die 261. However, at this time, it is avoided that the color image pickup element 210 and the ultraviolet ray cut glass plate 241 are pressed so as to abut on the particle 258. Mechanical damage caused by the particle 258 onto the upper face of the color image pickup element 210 can be reduced. More concretely, for example, a mounting case in an existing space of the particle of several μm in diameter will be referred. Thickness t of the visible light hardening type adhesive 60 may be set to about 10 μm. In particular, thickness t of the visible light hardening type adhesive 60 is preferably set to 10 μm or more.

In accordance with the above embodiment mode, the following effects can be obtained.

(8) As a manufacturing method of the color sensor for vehicle mounting, particularly, as a mounting method of the color image pickup element 210 of the first embodiment mode, as shown in FIGS. 25A to 25B, the color image pickup element 210 is mounted to the lead frame 250 (first process). As shown in FIGS. 27A to 27B, the color image pickup element 210 and the lead frame 250 are electrically connected by the bonding wire 251. The ultraviolet ray cut glass plate 241 is stuck to the upper face of the light receiving portion of the color image pickup element 210 by the visible light hardening type adhesive 60 (second process). As shown in FIGS. 24A to 24B, an area including the bonding wire 251 and removing at least the light receiving portion of the color image pickup element 210 is sealed by the mold resin 252 by using the die (the lower die 260 and the upper die 261) shown in FIG. 28 (third process). In this process, thickness t of the visible light hardening type adhesive 60 is set to be thicker than diameter D of the particle 258 in an atmospheric environment at a sticking time of the ultraviolet ray cut glass plate 241. Accordingly, mechanical damage caused by the particle to the color image pickup element can be reduced in the mold resin molding process.

### Tenth Embodiment Mode

FIG. 29 is a cross-sectional view of a color sensor for vehicle mounting in this embodiment mode instead of FIG. 19. In this embodiment mode, a transparent material is used as resin 270 for mold, and a transparent mold structure is set. The following construction is set more particularly.

In the color image pickup element 210, as shown in FIGS. 21A to 21C, many light receiving elements 20, 21, 22, 24 for outputting an electric signal according to the quantity of light are arrayed on the upper face of the substrate 10. Color filters 30, 31, 32, 34 are formed on the upper faces of the light receiving elements 20, 21, 22, 24.

As shown in FIG. 29, the color image pickup element 210 is mounted to the lead frame 250 (more particularly, die bond portion). The color image pickup element 210 and the lead frame 250 (more particularly, lead portion) are electrically connected by the bonding wire 251. The color image pickup element 210 including the bonding wire 251 is sealed by transparent mold resin 270. An ultraviolet ray cut filter 271 is formed on the surface of the transparent mold resin 270 above a light receiving portion (image pickup area) 10a of the color image pickup element 210. In FIG. 29, the ultraviolet ray cut filter 271 is formed on the entire upper face of the transparent mold resin 270 including an upper portion of the light receiving portion 210a. The ultraviolet ray cut filter 271 is constructed by a thin film. In the thin film construction of the ultraviolet ray cut filter 271, an aluminum oxide film (Al₂O₃) may be set to a first layer, and a titanium oxide film (TiO₂) and a silicon oxide film (SiO₂) may be also alternately laminated at a predetermined film thickness. Further, as shown in FIG. 29, an upper face 270a of the transparent mold resin 270 is set to a flat face, and the ultraviolet ray cut filter 271 is formed on this flat face. Accordingly, the ultraviolet ray cut filter 271 is easily arranged and is easily manufactured.

In accordance with the above embodiment mode, the following effects can be obtained.

(9) The color image pickup element 210 including the bonding wire 251 is sealed by the transparent mold resin 270 by adopting the mounting structure of the color image pickup element 210 shown in FIG. 29 so that it becomes excellent in humidity resisting property. Further, light resisting property of a color filter can be compensated by the ultraviolet ray cut filter 271. As its result, a color sensor for vehicle mounting excellent in humidity resisting property and light resisting property can be provided.

### Eleventh Embodiment Mode

FIG. 30 is a cross-sectional view of a color sensor for vehicle mounting in this embodiment mode instead of FIG. 19. FIG. 31 is an enlarged view of a main portion. In this embodiment mode, an ultraviolet ray cut filter 282 is formed on the color image pickup element (chip). The following construction is set more particularly.

In the color image pickup element 210, as explained in FIGS. 21A to 21C, many light receiving elements 20, 21, 22, 24 for outputting an electric signal according to the quantity of light are arrayed on the upper face of the substrate 10. As shown in FIG. 31, the red filter 30 is formed on the upper face of the light receiving element 20, and the green filters 31, 32 are formed on the upper faces of the light receiving element 21 and the light receiving element 22. The blue filter 34 is formed on the upper face of the light receiving element 24.

In FIG. 31, the light receiving elements 20, 21 (22), 24 are arranged transversally in a line on the substrate 10, but this arrangement is set for an explanation, and this arrangement is the same as FIGS. 21A to 21C.

As shown in FIG. 30, the color image pickup element 210 is mounted to the lead frame 250 (more particularly, die bond portion). The ultraviolet ray cut filter 282 is formed through an SOG film (Spin On Glass) 281 on the upper face of a light receiving portion (image pickup area) 10a of the color image pickup element 210. The ultraviolet ray cut filter 282 is constructed by a thin film. In the thin film construction of the ultraviolet ray cut filter 282, an aluminum oxide film (Al₂O₃) may be set to a first layer, and a titanium oxide film (TiO₂) and a silicon oxide film (SiO₂) may be also alternately laminated at a predetermined film thickness. When the ultraviolet ray cut filter 282 is constructed by a thin film, the ultraviolet ray cut filter 282 is easily arranged on the SOG film 281 and is easily manufactured.

Further, in FIG. 30, the color image pickup element 210 and the lead frame 250 (more particularly, lead portion) are electrically connected by the bonding wire 251. An area including the bonding wire 251 and removing at least the light receiving portion (image pickup area) 210a of the color image pickup element 210 is sealed by mold resin 283. More particularly, in the light receiving portion 210a in the color image pickup element 210, there is no mold resin 283 and the light receiving portion 210a is opened. Namely, an opening portion 284 is formed. Further, on a face opposed to the image pickup area in the color image pickup element 210 (substrate 10), there is also no mold resin 283 and this face is opened. Namely, an opening portion 285 is formed.

In accordance with the above embodiment mode, the following effects can be obtained.

(10) An area including the bonding wire 251 and removing at least the light receiving portion 210a of the color image pickup element 210 is sealed by the mold resin 283 by adopting the mounting structure of the color image pickup element 210 shown in FIGS. 30 and 31. Thus, it becomes excellent in humidity resisting property. Further, the light resisting property of a color filter can be compensated by the ultraviolet ray cut filter 282. As its result, a color sensor for vehicle mounting excellent in humidity resisting property and light resisting property can be provided.

The above embodiment mode may be also changed as follows.

As mentioned above, a case for the color sensor for vehicle mounting to the light controller has been described. Alternatively, another device may be provided for controlling the operation of the vehicle by judging a circumferential situation of the self vehicle.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A color sensor comprising:
a substrate;
first to third light receiving elements disposed on a surface of the substrate, wherein each of the first to third light receiving elements outputs an electric signal corresponding to an amount of light in an ultraviolet light range, a visible light range and a near infrared light range;
a red light filter for selectively passing a red light;
a first near infrared light block filter for blocking a near infrared light, wherein the first near infrared light block filter and the red light filter are disposed on the first light receiving element in this order;
a green light filter for selectively passing a green light;
a second near infrared light block filter for blocking the near infrared light, wherein the second near infrared light block filter and the green light filter are disposed on the second light receiving element in this order;
a visible light block filter for blocking a visible light, wherein the visible light block filter is disposed on the third receiving element; and
an ultraviolet light block plate disposed over the first and second near infrared light block filters and the visible light block filter.

2. The sensor according to claim 1, wherein
the first near infrared light block filter is disposed under the ultraviolet light block plate, and
the second near infrared light block filter is disposed under the ultraviolet light block plate.

3. The sensor according to claim 1, further comprising:
an adhesive member disposed between the substrate and the ultraviolet light block plate, wherein
the adhesive member is made of visible light curing adhesive.

4. The sensor according to claim 1, further comprising:
a fourth light receiving element disposed on the surface of the substrate;
a blue light filter for selectively passing a blue light; and
a third near infrared light block filter for blocking the near infrared light, wherein
the third near infrared light block filter and the fourth light receiving element are disposed on the fourth light receiving element, and
the ultraviolet light block plate is further disposed over the third near infrared light block filter.

5. The sensor according to claim 1, further comprising:
a fifth light receiving element disposed on the surface of the substrate, wherein
the fifth light receiving element is capable of receiving light through the ultraviolet light block plate without passing the light through the red and green light filters, the first and second near infrared light block filters and the visible light block filter.

6. The sensor according to claim 1, wherein
the first near infrared light block filter is made of a thin film,
the second near infrared light block filter is made of another thin film, and
the visible light block filter is made of further another thin film.

7. A method for manufacturing the color sensor according to claim 6, the method comprising:
arranging the first to third light receiving elements on the substrate;
forming the red light filter on the first light receiving element, and forming the green light filter on the second light receiving element;
forming a SOG film on a whole surface of the substrate including the red and green light filters; and
forming a thin film on the SOG film and patterning the thin film for providing the first and second near infrared light block filters; and forming another thin film on the SOG film and patterning the another thin film for providing the visible light block filter.

8. The method according to claim 7, wherein
the forming the red light filter and the forming the green light filter includes:
forming an electrode pad on the substrate, the method further comprising:
removing a part of the SOG film disposed on the electrode pad so that the electrode pad is exposed from the SOG film after the forming the thin film and the forming the another thin film.

9. The method according to claim 7, wherein
the forming the thin film on the SOG film is performed by a vapour deposition process.

10. The method according to claim 7, wherein
the forming the another thin film on the SOG film is performed by a vapour deposition process.

11. A color sensor comprising:
a silicon substrate having a first conductive type;
a first impurity diffusion region having a second conductive type and disposed on a surface portion of the substrate;
a second impurity diffusion region having the first conductive type and disposed on a surface portion of the first impurity diffusion region; and
a third impurity diffusion region having the second conductive type and disposed on a surface portion of the second impurity diffusion region, wherein
a boundary between the first impurity diffusion region and the substrate provides a first PN junction for photoelectric converting a near infrared light at the first PN junction,
a boundary between the second impurity diffusion region and the first impurity diffusion region provides a second PN junction for photoelectric converting a red light at the second PN junction, and
a boundary between the third impurity diffusion region and the second impurity diffusion region provides a third PN junction for photoelectric converting a green light at the second PN junction.

12. The sensor according to claim 11, further comprising:
a fourth impurity diffusion region having the first conductive type and disposed on a surface portion of the third impurity diffusion region, wherein
a boundary between the fourth impurity diffusion region and the third impurity diffusion region provides a fourth PN junction for photoelectric converting a blue light at the second PN junction.

13. A color sensor comprising:
a color image element including a substrate, a plurality of light receiving elements and a color filter, wherein each light receiving element is disposed on a surface of the substrate, and the color filter is disposed over the plurality of light receiving elements, and wherein each light receiving element outputs an electric signal corresponding to amount of light;
a lead frame, on which the color image element is disposed;
a bonding wire for electrically bonding the color image element and the lead frame;
a ultraviolet light block plate for blocking an ultraviolet light and made of glass, wherein the ultraviolet light block plate is bonded to a light receiving surface of the color image element with a visible light curing adhesion member; and
a resin mold for molding the bonding wire and the color image element other than the light receiving surface of the color image element.

14. The sensor according to claim 13, wherein
the ultraviolet light block plate has a light transmission rate of a light wavelength equal to or smaller than 350 nm, and
the light transmission rate is equal to or smaller than 10%.

15. The sensor according to claim 14, wherein
the light transmission rate of the ultraviolet light block plate is equal to or smaller than 1%.

16. The sensor according to claim 13, wherein
the bonding wire has a bonding portion to the substrate, and
the bonding portion is covered with the visible light curing adhesion member.

17. A method for manufacturing the color sensor according to claim 13, the method comprising:
mounting the color image element on the lead frame;
electrically coupling the color image element and the lead frame with the bonding wire;
bonding the ultraviolet light block plate to the light receiving surface of the color image element with the visible light curing adhesion member; and
sealing the bonding wire and the color image element other than the light receiving surface of the color image element with the resin mold by using a metal die, wherein
the visible light curing adhesion member has a thickness, which is larger than a diameter of a particle in atmosphere in the bonding the ultraviolet light block plate.

18. The method according to claim 17, wherein
the thickness of the visible light curing adhesion member is equal to or larger than 10 microns.

19. A color sensor comprising:
a color image element including a substrate, a plurality of light receiving elements and a color filter, wherein each light receiving element is disposed on a surface of the substrate, and the color filter is disposed over the plurality of light receiving elements, and wherein each light receiving element outputs an electric signal corresponding to amount of light;
a lead frame, on which the color image element is disposed;
a bonding wire for electrically bonding the color image element and the lead frame;
a transparent resin mold for molding the bonding wire and the color image element; and
a ultraviolet light block filter for blocking an ultraviolet light, wherein the ultraviolet light block filter is disposed on the transparent resin mold over a light receiving surface of the color image element.

20. The sensor according to claim 19, wherein
the transparent resin mold has an upper surface, which is flat, and
the ultraviolet light block filter is disposed on the upper surface of the transparent resin mold.

21. A color sensor comprising:
a color image element including a substrate, a plurality of light receiving elements and a color filter, wherein each light receiving element is disposed on a surface of the substrate, and the color filter is disposed over the plurality of light receiving elements, and wherein each light receiving element outputs an electric signal corresponding to amount of light;
a lead frame, on which the color image element is disposed;
a bonding wire for electrically bonding the color image element and the lead frame;
a ultraviolet light block filter for blocking an ultraviolet light, wherein the ultraviolet light block filter is disposed on a light receiving surface of the color image element through a SOG film; and
a resin mold for molding the bonding wire and the color image element other than the light receiving surface of the color image element.

22. The sensor according to claim 21, wherein
the ultraviolet light block filter is made of a thin film.
